(19) United States
(12) Patent Application Publication
(10) Pub. No.: US 2006/0145755 A1
(43) Pub. Date: Jul. 6, 2006

(54) Square wave modulation design for a class-D audio amplifier

(75) Inventors: Ming Hsiung Chen, Hsin Tien (TW); Shang Shu Chung, Hsin Tien (TW)

Correspondence Address: BACON & THOMAS, PLLC, 625 SLATERS LANE, FOURTH FLOOR, ALEXANDRIA, VA, 22314, US

(73) Assignee: Princeton Technology Corporation, Hsin Tien (TW)

(21) Appl. No.: 11/047,669

(22) Filed: Feb. 2, 2005

(30) Foreign Application Priority Data
Dec. 31, 2004 (TW) 093221494

(51) Int. Cl. H03F 3/38

(52) U.S. Cl. 330/10

(57) ABSTRACT

The present invention provides a square wave modulation design to control the frequency and phase of the carrier for a Class-D audio amplifier. In a half bridge-tied mode, the Class-D audio amplifier comprises a PWM (Pulse Width Modulator) for receiving an input signal and a square wave, a predriver and a power MOS circuit, the square wave controls the frequency and the phase of a carrier for the PWM, the power MOS circuit outputs signal for driving a loudspeaker. In a full bridge-tied mode, the Class-D audio amplifier comprises a PWM (Pulse Width Modulator) for receiving input signals and square waves, two predrivers and two power MOS circuits, the square waves control the modulation for the output carriers, the two power MOS circuits output signals respectively to pass through two filters to drive a loudspeaker cooperately. The present invention uses a simple square wave modulation to replace the triangular wave design for carrier modulation, thereby simplifies the circuit design of a Class-D audio amplifier and decreases the signal distortion.

### FIELD OF THE INVENTION

The present invention relates to an improvement for a Class-D audio amplifier design, and more particularly to a square wave modulation design for controlling the carrier frequency or the carrier phase of a Class-D audio amplifier.

### BACKGROUND OF THE INVENTION

Referring to FIG. 1, which shows schematically a circuit for a conventional Class-D audio amplifier. An audio signal Vᵢₙ is inputted from left to the two input terminals “a”, “b” of an operational amplifier 1. The operational amplifier 1 outputs two audio signals respectively to operational amplifier 2 and 3, and then via the predriver 4 and 5 for driving power CMOS circuits 6 and 7 to generate output signals OUTA and OUTB. Output signals OUTA and OUTB drive the loudspeaker 8 cooperatively, this is a push-pull type circuit, and is what so-called BTL (Bridge Tied Load) design. Resistors 9 and 10 are used for feedbacking signals; capacitors 11 and 12 are compensation circuits; inductors 13, 14 and capacitors 15, 16 are filter circuits. Triangular wave V_{triangular} of 500 KHz is inputted to operational amplifiers 2 and 3 for synchronizing the two carrier signals inputted to the operational amplifiers 2 and 3, therefore the phases of the carriers of output signals OUTA and OUTB will be the same with each other, as shown in FIG. 2(a); or the phases of the carriers of output signals OUTA and OUTB will have a phase shift of 180°, as shown in FIG. 2(b). The operational amplifiers 1, 2 and 3 cooperatively form a PWM (Pulse Width Modulator) for the Class-D audio amplifier. A PWM has varieties of design. FIG. 1 shows only one of them.

An additional triangular wave generator is required for generating the triangular wave V_{triangular}, but a triangular wave generator is very complicated in design and is not very easy to generate very accurate triangular wave. An additional triangular wave generator will occupy too much space in an IC design, thus increasing cost. The triangular wave V_{triangular} for synchronizing the two carrier signals of the output signals OUTA and OUTB can be replaced by a simple square wave for decreasing the manufacturing cost.

### SUMMARY OF THE INVENTION

It is therefore an object of the invention to provide a square wave modulation design for controlling the carrier frequency or carrier phase of a Class-D audio amplifier. A half bridge-tied mode of the present invention comprises a PWM (Pulse Width Modulator) for receiving an input signal and a square wave, a predriver and a power MOS circuit; in which the square wave will control the mudulation frequency of an output carrier, while the power MOS circuit will output signal to drive a loudspeaker. A full bridge-tied mode of the present invention comprises a PWM (Pulse Width Modulators) for receiving two input signal and two square waves, two predrivers and two power MOS circuits, thereby forming two signal routes, in which the square wave will control the mudulation frequency of the output carriers of the two signal routes, while the two power MOS circuits will output signals to drive a loudspeaker cooperately. The present invention uses a simple square wave modulation to replace the triangular wave design for carrier modulation, thereby simplifies the circuit design of a Class-D audio amplifier and decreases the signal distortion.

### BRIEF DESCRIPTION OF THE DRAWINGS

FIG. 1 shows schematically a conventional circuit for a Class-D audio amplifier.

FIG. 2 shows schematically the output signals of the conventional Class-D audio amplifier.

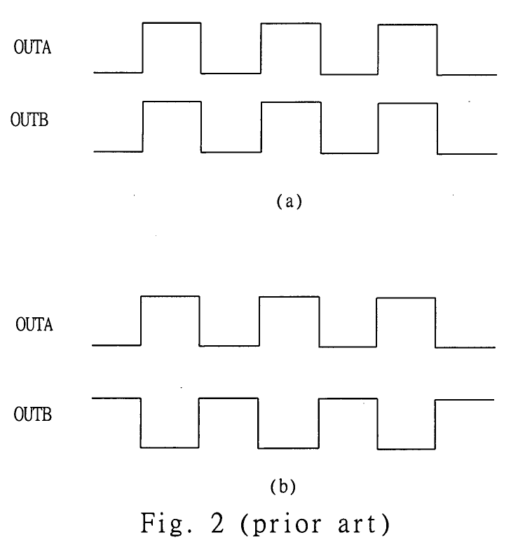

FIG. 3 shows schematically the block diagram of a half bridge-tied Class-D audio amplifier according to the present invention.

FIG. 4 shows schematically the circuit diagram of the half bridge-tied Class-D audio amplifier according to the present invention.

FIG. 5 shows schematically the block diagram of a full bridge-tied Class-D audio amplifier according to the present invention.

FIG. 6 shows schematically the circuit diagram of the full bridge-tied Class-D audio amplifier according to the present invention.

FIG. 7 shows schematically another circuit diagram of a full bridge-tied Class-D audio amplifier according to the present invention.

### DETAILED DESCRIPTION OF THE EMBODIMENTS

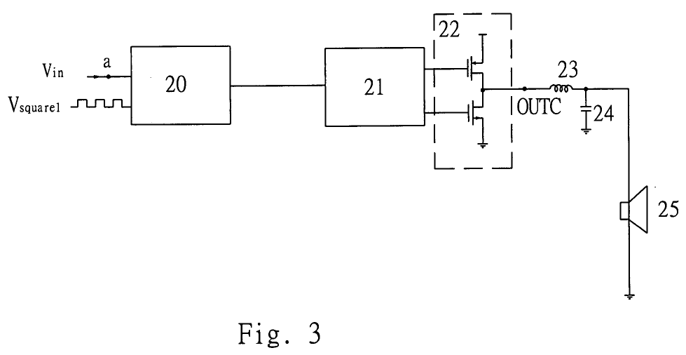

Referring to FIG. 3, which shows schematically the block diagram of a half bridge-tied Class-D audio amplifier according to the present invention. An audio signal Vᵢₙ is inputted from left to an input terminals “a” of a PWM (Pulse Width Modulator) 20, and a square wave V_{square1} is also inputted to the PWM 20, as shown in FIG. 3. PWM 20 outputs audio signal to a predriver 21 for driving power CMOS circuit 22 to generate output signal OUTC. Output signal OUTC passes through a filter of inductor 23 and capacitor 24 to drive the loudspeaker 25. This is a half bridge-tied Class-D audio amplifier design.

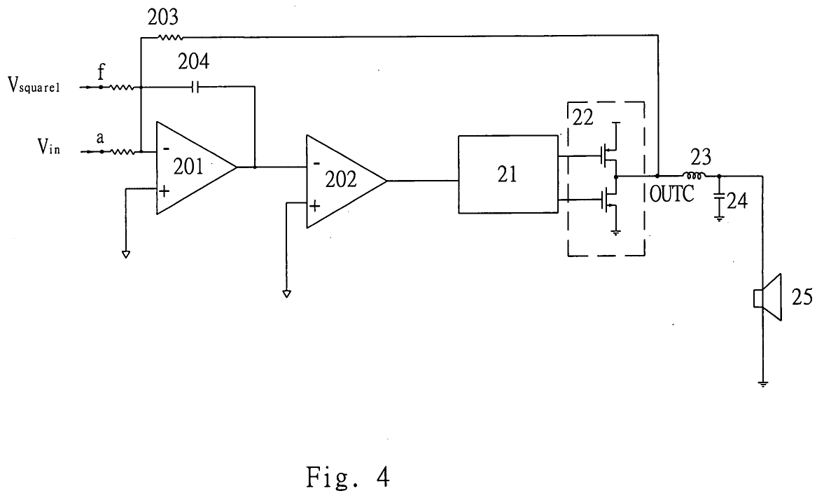

Referring to FIG. 4, which shows schematically the circuit diagram of the half bridge-tied Class-D audio amplifier according to the present invention. An audio signal Vᵢₙ is inputted from left to an input terminal “a” of an operational amplifier 201. Operational amplifier 201 outputs audio signal to an operational amplifier 202 for driving a predriver 21 and a power CMOS circuit 22 thereafter for generating output signal OUTC. The output signal OUTC passes through a filter of inductor 23 and capacitor 24 to drive the loudspeaker 25. This is a half bridge-tied Class-D audio amplifier design. Resistor 203 is used for feedbacking signal, capacitor 204 is a compensation circuit, inductor 23 and capacitor 24 are used for filtering. Operational amplifier 201 and operational amplifier 202 form what so called a PWM (Pulse Width Modulator). A square wave V_{square1} is inputted to terminal “f” for modulation. V_{square1} is a square wave of fixed frequency or non-fixed frequency. A PWM has varieties of design. FIG. 4 shows only one of them.

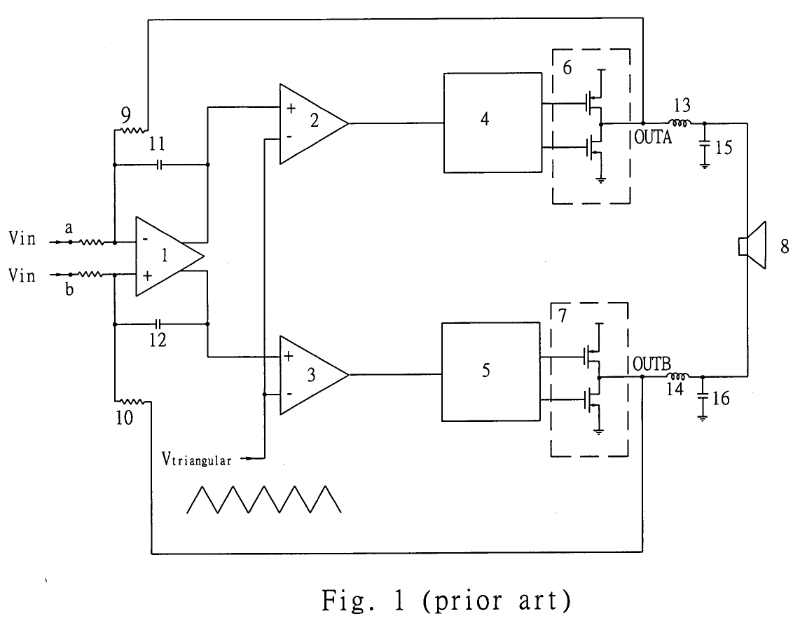

The most important feature in FIG. 4 is that a square wave V_{square1} is used for replacing the triangular wave V_{triangular} of 500 KHz in FIG. 1, and V_{square1} is able to control the carrier frequency of the output signal OUTC. This circuit omits a complicated triangular wave generator, and a square wave circuit design is much easier than a triangular wave circuit design, saving the circuit space in IC design, thereby decreasing cost.

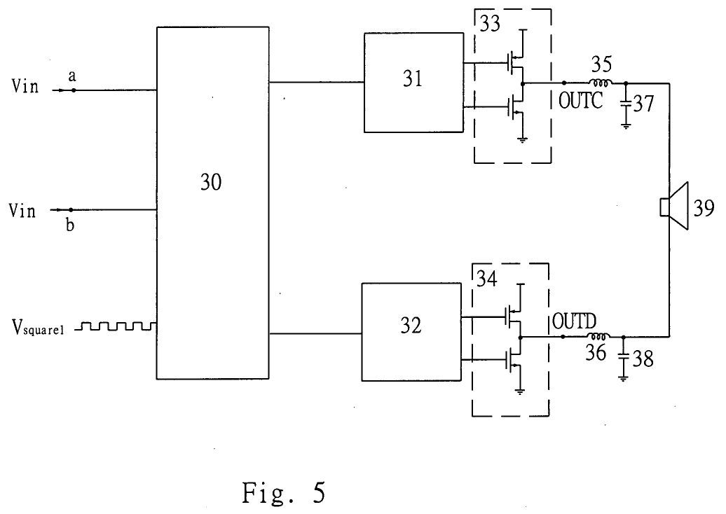

Referring to FIG. 5, which shows schematically the block diagram of a full bridge-tied Class-D audio amplifier according to the present invention. An audio signal Vᵢₙ is inputted from left to input terminals “a” and “b” of a PMW 30, and a square wave or two square waves is/are also inputted to the PWM 30. PWM 30 outputs two audio signals respectively to predrivers 31 and 32 for driving power CMOS circuits 33 and 34 to generate output signals OUTC and OUTD. The output signals OUTC and OUTD respectively pass through two filters of inductors 35, 36 and capacitors 37, 38 to drive the loudspeaker 25 cooperately. This is a push-pull type circuit, and is what so-called BTL (Bridge Tied Load) design.

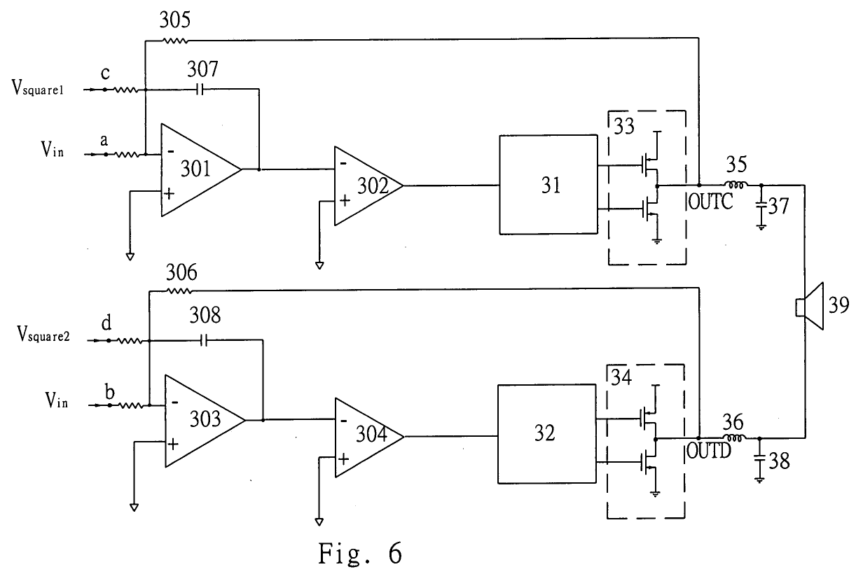

Referring to FIG. 6, which shows schematically the circuit diagram of the full bridge-tied Class-D audio amplifier according to the present invention, wherein the detailed circuit of the PWM 30 in FIG. 5 is demonstrated, while other parts remain the same as in FIG. 5. PWM 30 is divided into two parts, one comprises operational amplifiers 301 and 302, the other comprises operational amplifiers 303 and 304, each part receives audio signal Vᵢₙ respectively at points “a”, “b”, and also receives square waves V_{square1}, V_{square2} respectively at points “c”, “d”. V_{square1}, V_{square2} are square waves of fixed frequency or non-fixed frequency, and have fixed phase shift or non-fixed phase shift. Resistors 305, 306 are used for feedbacking signals, capacitors 307, 308 are compensation circuits. The PWM has varieties of design. FIG. 6 shows only one of them.

The most important feature in FIG. 6 is that square waves V_{square1}, V_{square2} are used for replacing the triangular wave V_{triangular} of 500 KHz in FIG. 1, and V_{square1}, V_{square2} are able to control the carrier frequency and carrier phase of the output signals OUTC and OUTD. This circuit omits a complicated triangular wave generator, and a square wave circuit design is much easier than a triangular wave circuit design, saving the circuit space in IC design, thereby decreasing cost.

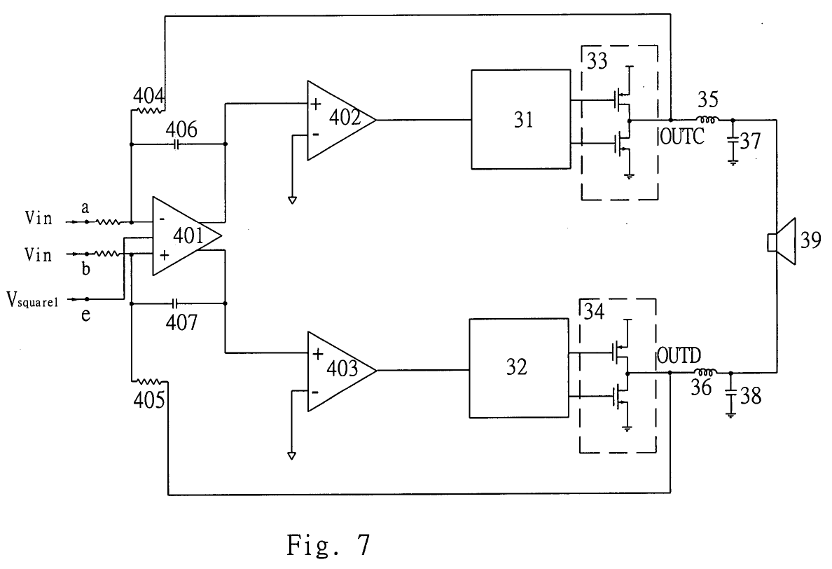

Referring to FIG. 7, which shows schematically another circuit diagram of a full bridge-tied Class-D audio amplifier according to the present invention, wherein operational amplifiers 401, 402, 403 are used for replacing operational amplifiers 301, 302, 303 and 304, while other parts remain the same as in FIG. 6. An audio signal Vᵢₙ is inputted from left to input terminals “a” and “b” of the operational amplifier 401, and the operational amplifier 401 outputs two audio signals respectively to operational amplifiers 402 and 403, and then via the predrivers 31 and 32 for driving power CMOS circuits 33 and 34 to generate output signals OUTC and OUTD. The output signals OUTC and OUTD pass through filters to drive the loudspeaker 8 cooperatively. This is what so-called BTL (Bridge Tied Load) design. Resistors 404 and 405 are used for feedbacking signals; capacitors 406 and 407 are compensation circuits; inductors 35, 36 and capacitors 37, 38 are filter circuits. Operational amplifier 401 and operational amplifiers 402, 403 form what so-called PWM (Pulse Width Modulator). A square wave V_{square1} is inputted to an input terminal “e” of the operational amplifier 401 as a modulation signal.

The most important feature in FIG. 7 is that the square wave V_{square1} is used for replacing the triangular wave V_{triangular} of 500 KHz in FIG. 1, and V_{square1} is able to control the carrier frequency and carrier phase of the output signals OUTC and OUTD. This circuit omits a complicated triangular wave generator, and a square wave circuit design is much easier than a triangular wave circuit design, saving the circuit space in IC design, thereby decreasing cost.

Each of the above-mentioned power CMOS circuits can be replaced by a power MOS circuit.

The spirit and scope of the present invention depend only upon the following Claims, and are not limited by the above embodiments.

What is claimed is:

1. A square wave modulation design for a half bridge-tied Class-D audio amplifier, the Class-D audio amplifier comprises a PWM (Pulse Width Modulator) for receiving an input signal and a square wave, a predriver and a power MOS circuit, connected serially; the power MOS circuit outputs an output signal for driving a loudspeaker; the square wave controls the frequency and the phase of a carrier for the PWM, and further controls the frequency and the phase of a carrier for the output signal of the Class-D audio amplifier; and the power MOS circuit feeds back a signal to the PWM.

2. A square wave modulation design for a full bridge-tied Class-D audio amplifier, the Class-D audio amplifier comprises a PWM (Pulse Width Modulator) for receiving two input signals and two square waves, two predrivers and two power MOS circuits;
the PWM outputs two audio signals respectively to the two predrivers for driving the two power MOS circuits; the two power MOS circuits output signals respectively to pass through two filters to drive a loudspeaker cooperately; the two square waves respectively control the frequency and phase of two carriers of the PWM, and further control the frequency and phase of the carriers for the two output signals of the Class-D audio amplifier; the two power MOS circuits feedback signals respectively to the PMW.

3. A square wave modulation design for a full bridge-tied Class-D audio amplifier, the Class-D audio amplifier comprises a PWM (Pulse Width Modulator) for receiving two input signals and a square wave, two predrivers and two power MOS circuits;
the PWM outputs two audio signals respectively to the two predrivers for driving the two power MOS circuits; the two power MOS circuits output signals respectively to pass through two filters to drive a loudspeaker cooperately; the square wave controls the frequency and phase of the carrier of the PWM, and further controls the frequency and phase of the carriers for the two output signals of the Class-D audio amplifier; the two power MOS circuits feedback signals respectively to the PMW.

4. A square wave modulation design for a half bridge-tied Class-D audio amplifier according to claim 1, wherein each of the power MOS circuit is a power CMOS circuit.

5. A square wave modulation design for a full bridge-tied Class-D audio amplifier according to claim 2, wherein each of the power MOS circuit is a power CMOS circuit.

6. A square wave modulation design for a full bridge-tied Class-D audio amplifier according to claim 3, wherein each of the power MOS circuit is a power CMOS circuit.
